(19) United States
(12) Patent Application Publication
(10) Pub. No.: US 2014/0264848 A1
(43) Pub. Date: Sep. 18, 2014

(54) SEMICONDUCTOR PACKAGE AND METHOD FOR FABRICATING THE SAME

(71) Applicant: SK hynix Inc., Gyeonggi-do (KR)

(72) Inventors: Ho-Young SON, Gyeonggi-do (KR); Byung-Wook BAE, Gyeonggi-do (KR); Jong-Hoon KIM, Gyeonggi-do (KR); Han-Jun BAE, Gyeonggi-do (KR)

(73) Assignee: SK hynix Inc., Gyeonggi-do (KR)

(21) Appl. No.: 14/153,870

(22) Filed: Jan. 13, 2014

Related U.S. Application Data
(63) Continuation-in-part of application No. 13/830,361, filed on Mar. 14, 2013.

(51) Int. Cl. H01L 23/498

(52) U.S. Cl. CPC H01L 23/49811; H01L 23/49827
USPC 257/737

(57) ABSTRACT

A semiconductor package includes through-substrate vias each penetrating through a semiconductor substrate and having a protrusion that is protruded from the backside of the semiconductor substrate, and a passivation layer formed on a sidewall of the protrusion and the backside of the semiconductor substrate, wherein a bottom surface of the protrusion and a bottom surface of the passivation layer are substantially coplanar.

### CROSS-REFERENCE TO RELATED APPLICATIONS

This application is a continuation-in-part of application Ser. No. 13/830,361 filed on Mar. 14, 2013, which is incorporated herein by reference in its entirety.

### BACKGROUND

1. Field

The disclosure relates to a semiconductor device, and more particularly, to a semiconductor package including through-electrodes, and a method for fabricating the semiconductor package.

2. Description of the Related Art

As electronic products become smaller and more functional, there is a need to include more chips in the smaller products to meet the required function. As a demand for semiconductor devices with low-cost, high performance, increased miniaturization, and greater packaging densities has increased, devices having multiple dies, such as multi-chip packages, have been developed to meet the demand.

A multi-chip package includes a plurality of semiconductor chips stacked within a single semiconductor package. Through-substrate via (also referred to herein as TSV) technology provides vertical electrical connections in a multi-chip package. Through-substrate vias are vertical electrical connections that extend through the full thickness of the wafer, i.e., from one of the electrically conductive levels formed on the topside semiconductor surface of the integrated circuit (IC) die (e.g., a contact level or one of the back end of line (BEOL) metal interconnect levels) to the bottom side semiconductor surface of the IC die. The vertical electrical paths are significantly shortened relative to conventional wire bonding technology.

### SUMMARY

Exemplary embodiments of the present invention are directed to a semiconductor package where each semiconductor chip has a backside structure for stable bonding with another chip, and a method for fabricating the semiconductor package.

In accordance with an exemplary embodiment of the present invention, a through-substrate via structure includes a semiconductor substrate through which an ion of a metal is diffusible, a through-substrate via including a through-electrode penetrating through the semiconductor substrate and having a protrusion that protrudes from the backside of the semiconductor substrate, and a passivation layer formed on a sidewall of the protrusion and the backside of the semiconductor substrate, wherein a bottom surface of the protrusion and a bottom surface of the passivation layer are substantially coplanar, wherein the passivation layer includes a first insulation layer formed on the sidewalls of the protrusion of the through-substrate vias and the backside of the semiconductor substrate, and a second insulation layer formed over the first insulation layer.

In accordance with another exemplary embodiment of the present invention, a semiconductor package includes through-substrate vias each penetrating through a semiconductor substrate and having a protrusion that protrudes from the backside of the semiconductor substrate, and a passivation layer formed on a sidewall of the protrusion and the backside of the semiconductor substrate, wherein a bottom surface of the protrusion and a bottom surface of the passivation layer are substantially coplanar, wherein the passivation layer includes a first insulation layer formed on the sidewall of the protrusion of the through-substrate vias and the backside of the semiconductor substrate, a second insulation layer formed over the first insulation layer, and a third insulation layer formed over the second insulation layer.

### BRIEF DESCRIPTION OF THE DRAWINGS

FIG. 1 is a cross-sectional view illustrating a semiconductor package in accordance with an embodiment of the present invention;

FIG. 2 is a cross-sectional view illustrating a semiconductor package in accordance with an embodiment of the present invention;

FIG. 3A and FIG. 3B are cross-sectional views illustrating embodiments having bumps on the semiconductor packages of FIG. 1 and FIG. 2, respectively;

FIG. 4A and FIG. 4B are cross-sectional views illustrating embodiments having bumps on the semiconductor packages of FIG. 1 and FIG. 2, respectively;

FIGS. 5A to 5D are cross-sectional views illustrating a process of fabricating the semiconductor package in accordance with an embodiment of the present invention;

FIGS. 6A to 6D are cross-sectional views illustrating a process of fabricating the semiconductor package in accordance with an embodiment of the present invention;

FIG. 7 is a system block diagram illustrating an electronic apparatus that may include the semiconductor package in accordance with an embodiment of the present invention; and

FIG. 8 is a block diagram illustrating an electronic apparatus that may include the semiconductor package in accordance with an embodiment of the present invention.

### DETAILED DESCRIPTION

Various exemplary implementations of the present invention will be described below in more detail with reference to the accompanying drawings. The present invention may, however, be embodied in different forms and should not be construed as limited to the exemplary implementations set forth herein. Rather, these exemplary implementations are provided so that this disclosure will be thorough and complete, and will fully convey the scope of the present invention to those skilled in the art. Throughout the disclosure, reference numerals correspond directly to the like numbered parts in the various figures and exemplary implementations of the present invention.

The drawings are not necessarily to scale and in some instances, proportions may have been exaggerated in order to clearly illustrate features of the implementations. It should be readily understood that the meaning of “on” and “over” in the present disclosure should be interpreted in the broadest manner such that “on” means not only “directly on” but also “on” something with an intermediate feature(s) or a layer(s) in between, and that “over” means not only directly on top but also on top of something with an intermediate feature(s) or a layer(s) in between.

It is also noted that in this specification, “connected/coupled” refers to one component not only directly coupling another component but also indirectly coupling another component through an intermediate component. In addition, a singular form may include a plural form as long as it is not specifically mentioned in a sentence.

Referring to FIG. 1, the semiconductor package having a TSV structure includes a semiconductor substrate 100 having a front side A and a backside B. The semiconductor substrate 100 may be a metal-diffusible substrate including a silicon substrate. The metal-diffusible substrate is a substrate that metal ions could diffuse through the substrate. The semiconductor substrate 100 has a through-via 103. The through-via 103 may penetrate the semiconductor substrate 100 from the front side A to the backside B. Although not illustrated in the drawing, the through-via 103 may be a blind via. When the through-via 103 is a blind via, the through-via 103 is connected to active circuitry (not shown) on the front side A through connection members (not shown).

A through-substrate via 102 is formed in the inside of the through-via 103. The through-substrate via 102 has a protrusion 102A that protrudes from the backside B of the semiconductor substrate 100.

The through-substrate via 102 includes a liner layer 101A and a through-electrode 101C. The through-substrate via 102 may further include a barrier layer 101B.

The through-electrode 101C may be formed of a diffusible metal. The diffusible metal may be ionized and the ionized metal may be diffused through a metal-diffusible substrate such as the semiconductor substrate 100. The diffusible metal is selected from the group consisting of copper (Cu) tin (Sn), silver (Ag), and combinations thereof.

The liner layer 101A may be formed between the through-electrode 101C and the semiconductor substrate 100. The liner layer 101A may be formed of an insulation material selected from the group consisting of an oxide, e.g., SiOₓ, a nitride, e.g., SiNₓ, and a polymer. The liner layer 101A may be conformally formed along the internal sidewalls of the through-via 103.

The barrier layer 101B for preventing the diffusion of the metal into the semiconductor substrate 100 may be formed between the liner layer 101A and the through-electrode 101C. The barrier layer 101B may be formed of a material selected from the group consisting of titanium (Ti), tantalum (Ta), tungsten (W), titanium nitride (TIN), tantalum nitride (Tan tungsten nitride (WₓN_{y}), tantalum silicon nitride (TaSiN), titanium silicon nitride (TiSiN), tungsten silicon nitride (WSiN), manganese (Mn), ruthenium (Ru), and combinations thereof.

When the liner layer 101A is formed of a nitride, e.g., SiN or Si₃N₄, the liner layer 101A may serve as a barrier layer against diffusible metal. Therefore, it does not have to form the barrier layer 101B.

The liner layer 101A and the barrier layer 101B may be conformally formed on the sidewalls of the through-electrode 101C, and they may be formed even on the sidewalls of the protrusion 102A. A bottom surface S of the protrusion 102A is not covered with the liner layer 101A and the barrier layer 101B.

A passivation layer 106 is formed on the backside B of the semiconductor substrate 100. The passivation layer 106 may be formed to have a height from the backside B of the semiconductor substrate 100 to the bottom surface S of the protrusion 102A. The passivation layer 106 may include a first insulation layer 104A and a second insulation layer 105A. The first insulation layer 104A is formed on the backside B of the semiconductor substrate 100 and the sidewalls of the protrusion 102A. The first insulation layer 104A formed on the sidewalls of the protrusion 102A and the first insulation layer 104A formed on the backside of the semiconductor substrate 100 may be perpendicular.

The through-substrate via 102 including the protrusion 102A and the first insulation layer 104A formed on the sidewalls of the protrusion 102A may be coaxial. That is, the first insulation layer 104A formed on the sidewalls of the protrusion 102A is formed to surround the protrusion 102A. The first insulation layer 104A formed on the backside B of the semiconductor substrate 100 is connected with the first insulation layer 104A formed on the sidewalls of the protrusion 102A to inhibit the diffusion of a contaminant into the semiconductor substrate 100.

The first insulation layer 104A may be formed conformally. The second insulation layer 105A may be formed on the first insulation layer 104A. The first insulation layer 104A may surround the second insulation layer 105A except a bottom surface of the second insulation layer 105A. The second insulation layer 105A is a buffering layer that alleviates a pressure on the passivation layer 106 induced by a subsequent planarization process or a physical stress on the passivation layer 106 induced by a reliability test process.

The bottom surface S of the protrusion 102A and a bottom surface of the passivation layer 106 may be coplanar. That is, the bottom surface S of the protrusion 102A is formed to be horizontally aligned with the bottom surface of the passivation layer 106.

In accordance with the exemplary implementation described above, the first insulation layer 104A is a metal barrier layer including a nitride layer or a silicon oxynitride layer, and the second insulation layer 105A may be a buffering layer including an oxide layer. The metal barrier layer formed on the backside of the semiconductor substrate 100 inhibits the diffusion of a contaminant into the semiconductor substrate 100 through the backside B of the semiconductor substrate 100.

The metal barrier layer formed on the sidewalls of the protrusion 102A inhibits the diffusion of a contaminant into the semiconductor substrate 100 along the sidewalls of the through-substrate vias 102.

If the first insulation layer 104A is formed of an oxide layer, the first insulation layer 104A functions as a buffering layer. The buffering layer may reduce the stress of the passivation layer 106.

Further, if the second insulation layer 105A is formed of a nitride layer or a silicon oxynitride layer, the second insulation layer 105A functions as a metal barrier layer. The metal barrier layer may inhibit the diffusion of a contaminant into the semiconductor substrate 100.

Referring to FIG. 2, the semiconductor package having a TSV structure includes a semiconductor substrate 100, through-substrate vias 102 each having a protrusion 102A, a liner layer 101A, a barrier layer 101B, and a through-electrode 101C. The TSV structure includes a first insulation layer 210A, a second insulation layer 220A, and a third insulation layer 230A such as a passivation layer 200 on the backside B of the semiconductor substrate 100.

Since the semiconductor substrate 100, the through-substrate vias 102 each having the protrusions 102A, the liner layer 101A, the barrier layer 101B, and the through-electrode 101C are already described in the exemplary implementation in FIG. 1 above, descriptions of them are omitted.

A passivation layer 200 is formed on the backside B of the semiconductor substrate 100. The passivation layer 200 may be formed to have a height from the backside B of the semiconductor substrate 100 to the bottom surface S of the protrusion 102A. The passivation layer 200 may include a first insulation layer 210A, a second insulation layer 220A and a third insulation layer 230A.

The first insulation layer 210A may be formed on the backside B of the semiconductor substrate 100 and the sidewalls of the protrusion 102A. The first insulation layer 210A formed on the sidewalls of the protrusion 102A and the first insulation layer 210A formed on the backside of the semiconductor substrate may be perpendicular. The first insulation layer 210A inhibits the diffusion of a contaminant into the semiconductor substrate 100. The contaminant may include a metal ion.

The through-substrate via 102 including the protrusion 102A and the first insulation layer 210A formed on the sidewalls of the protrusion 102A may be coaxial. The first insulation layer 210A may be formed conformally. That is, the first insulation layer 210A formed on the sidewalls of the protrusion 102A is formed to surround the protrusion 102A. The first insulation layer 210A formed on the backside B of the semiconductor substrate 100 is connected with the first insulation layer 210A formed on the sidewalls of the protrusion 102A to inhibit the diffusion of a contaminant into the semiconductor substrate 100. The first insulation layer 210A may be formed conformally. The first insulation layer 210A may repress the diffusion of a contaminant into the semiconductor substrate 100 through the backside B of the semiconductor substrate 100 and through the sidewalls of the through-substrate vias 102.

The second insulation layer 220A may be formed on the first insulation layer 210A. The first insulation layer 210A may surround the second insulation layer 220A except a bottom surface of the second insulation layer 220A. The second insulation layer 220A is a buffering layer that alleviates a pressure on the passivation layer 200 induced by a subsequent planarization process or a physical stress on the passivation layer 200 induced by a reliability test process.

The third insulation layer 230A may be formed on the second insulation layer 220A. The third insulation layer 230A is conformally formed along a profile of the bottom surface of the second insulation layer 220A, thereby covering the second insulation layer 220A except two ends of the second insulation layer 220A adjacent to the protrusion 102A. The third insulation layer 230A inhibits the diffusion of a contaminant on a bottom surface of passivation layer 200 from an end of one TSV to an end of another TSV.

The bottom surface S of the protrusions 102A and the bottom surface of the passivation layer 200 may be coplanar. That is, the bottom surface S of the protrusions 102A is formed to be horizontally aligned with the bottom surface of the passivation layer 200.

According to one embodiment of the present invention, the first insulation layer 210A may be a first metal barrier layer including a nitride layer or a silicon oxynitride layer, the second insulation layer 220A may be a buffering layer including an oxide layer, and the third insulation layer 230A may be a second metal barrier layer including a nitride layer or a silicon oxynitride layer.

The first insulation layer 210A may repress the diffusion of a contaminant into the semiconductor substrate 100 through the backside B of the semiconductor substrate 100 and through the sidewalls of the through-substrate vias 102. The second insulation layer 220A may reduce the stress of the passivation layer 200. The third insulation layer 230A may repress the diffusion of a contaminant on the bottom surface of the passivation layer 200.

Referring to FIGS. 3A to 3B, the semiconductor packages having TSV structures include a semiconductor substrate 100, through-substrate vias 102 each having a protrusion 102A, a liner layer 101A, a barrier layer 101B, a through-electrode 101C, and a passivation layer 106 or 200. The semiconductor packages may further include bumps 410 formed on the bottom surfaces S of the protrusions 102A.

Since the semiconductor substrate 100, the through-substrate vias 102 each having the protrusion 102A, the liner layer 101A, the barrier layer 101B, the through-electrode 101C, and the passivation layers 106 and 200 are described in the formerly-described embodiment of the present invention, descriptions of them are omitted. The barrier layer 101B may be omitted.

The bumps 410 may be formed to contact entire portions of the bottom surfaces S of the protrusions 102A. Also, the bumps 410 may be formed to be stretched to the bottom surfaces of the passivation layers 106 and 200 formed adjacent to the protrusions 102A. That is, the bumps 410 may be formed to cover the entire portions of the bottom surfaces S of the protrusions 102A and partial portions of the bottom surfaces of the passivation layers 106 and 200.

The bumps 410 may include a three-layered metal bump. In an embodiment, the bumps 410 may include a copper (Cu) layer 410A, a nickel (Ni) layer 410B, and a gold (Au) layer 410C, which are sequentially stacked on the bottom surface S of the protrusion 102A. In an embodiment, the bumps 410 may include a nickel (Ni) layer 410A, a palladium (Pd) layer 410B, and a gold (Au) layer 410C. Although not illustrated in the figures, the bumps 410 may include a two-layered metal bump. The bumps 410 may include a nickel (Ni) layer and a gold (Au) layer. The bumps 410 may include a nickel (Ni) layer and a palladium (Pd) layer. The bumps 410 may include a palladium (Pd) layer and a gold (Au) layer. Although not illustrated in the figures, the bumps 410 may include a single-layered metal bump. The bumps 410 may include a gold (Au) layer.

Although not illustrated, an adhesion layer and a seed layer may be formed between the bumps and the bottom surfaces S of the protrusions 102A. When the bumps 410 are formed to be stretched to the bottom surfaces of the passivation layers 106 and 200 formed around the protrusions 102A, the adhesion layer and the seed layer also may be formed between the bumps and the bottom surfaces of the passivation layers 106 and 200. The adhesion layer may be formed of a material selected from the group consisting of titanium (Ti), tantalum (Ta), titanium nitride (TiN), tantalum nitride (TaN), titanium tungsten (TiW), nickel vanadium (NiV), and combinations thereof. The seed layer may be formed of a material selected from the group consisting of copper (Cu), nickel (Ni), and gold (Au).

The passivation layers 106 and 200 inhibit the diffusion of a contaminant including a metal ion from the through-electrode 101C or the bumps 410 into the semiconductor substrate 100. The semiconductor substrate 100 is insulated from the through-electrode 101C by the passivation layers 106 and 200, so that stability of the semiconductor package having a TSV structure is secured. Electrical bridges between the semiconductor substrate 100 and the bumps 410 may be prevented by the passivation layers 106 and 200.

Referring to FIGS. 4A to 48, the semiconductor packages include a semiconductor substrate 100, through-substrate vias 102 each having a protrusion 102A, a liner layer 101A, a barrier layer 101B, a through-electrode 101C, and a passivation layer 106 and 200. The semiconductor packages may further include bumps 510 formed on the bottom surfaces S of the protrusions 102A.

Since the semiconductor substrate 100, the through-substrate vias 102 each having the protrusion 102A, the liner layer 101A, the barrier layer 101B, the through-electrode 101C, and the passivation layers 105 and 200 are described in the formerly-described embodiments of the present invention, descriptions of them are omitted.

The bumps 510 may be formed to contact partial portions of the bottom surfaces S of the protrusions 102A. Also, the bumps 510 may be formed to be stretched to the bottom surfaces of the passivation layers 106 and 200. That is, the bumps 510 may be formed to cover the partial portions of the bottom surfaces S of the protrusions 102A and partial portions of the bottom surfaces of the passivation layers 106 and 200. Herein, the bottom surfaces S of the protrusions 102A are not entirely covered by the bumps 510.

The bumps 510 may include a three-layered metal bump. In an embodiment, the bumps 510 may include a copper (Cu) layer 510A, a nickel (Ni) layer 510B, and a gold (Au) layer 510C, which are sequentially stacked on the bottom surface S of the protrusion 102A. In an embodiment, the bumps 410 may include a nickel (Ni) layer 510A, a palladium (Pd) layer 510B, and a gold (Au) layer 510C. Although not illustrated in the figures, the bumps 510 may include a two-layered metal bump as the formerly-described embodiment. Although not illustrated in the figures, the bumps 410 may include a single-layered metal bump as the formerly-described embodiment.

The passivation layers 106 and 200 inhibit the diffusion of a contaminant including a metal ion from the through-electrode 101C or the bumps 510 into the semiconductor substrate 100. The semiconductor substrate 100 is insulated from the through-electrode 101C by the passivation layers 106 and 200, so that stability of the semiconductor package having a TSV structure is secured. Electrical bridges between the semiconductor substrate 100 and the bumps 510 may be prevented by the passivation layers 106 and 200. That is, even though the bumps 510 do not entirely cover the bottom surfaces S of the protrusions 102A, due to misalignment, an electrical bridge between the semiconductor substrate 100 and the bumps 510 may be prevented.

Referring to FIG. 5A, through-substrate vias 102 are formed to penetrate through a semiconductor substrate 100. Hereafter, a method for forming the through-substrate vias 102 is described. Through-vias 103 may be formed by etching the semiconductor substrate 100, or a wafer obtained after a predetermined process is performed, in a predetermined depth from the front side A of the semiconductor substrate 100. Subsequently, a liner layer 101A and a barrier layer 101B may be formed in the inside of each through-via 103. When the barrier layer 101B is omitted, the liner layer 101A is formed in the inside of each through-via 103. Subsequently, through-electrodes 101C may be formed as the through-vias 103 are filled with a conductive layer by depositing a conductive material. Although not illustrated in the drawings, a circuit may be formed by performing a process of forming metal lines on the front side A of the semiconductor substrate 100. The circuit may be electrically connected to the through-electrodes 101C. Subsequently, the backside B of the semiconductor substrate 100 may be polished. The polishing process may be performed in two steps. In the first step the backside B of the semiconductor substrate 100 may be physically polished, and in the second step a dry etch process or a chemical-mechanical polishing (CMP) process may be performed on the backside B of the semiconductor substrate 100. The physical polishing may be a back grinding process. As a result of the polishing process, the through-substrate vias 102 come to have protrusions 102A that protrude from the backside B of the semiconductor substrate 100. The liner layer 101A and the barrier layer 101B may cover the surface of the through-electrode 101C of the protrusion 102A.

Referring to FIG. 5B, a first insulation layer 104 and a second insulation layer 105 may be stacked on the backside B of the semiconductor substrate 100. The first insulation layer 104 may be formed on the backside B of the semiconductor substrate 100. The first insulation layer 104 may be formed on the sidewalls of the protrusions 102A. The first insulation layer 104 may be formed conformally. The second insulation layer 105 may be formed on the first insulation layer 104.

Referring to FIG. 5C, the first insulation layer 104 and the second insulation layer 105 are planarized. The planarization process may be a CMP process or a mechanical polishing process. The planarization process may be performed to reveal the through-electrodes 101C. As a result of the planarization process, the bottom surfaces S of the protrusions 102A are exposed.

The patterned first insulation layer 104A and the patterned second insulation layer 105A obtained as a result of the planarization process are referred to as a passivation layer 106 for convenience in the description. The bottom surface S of the protrusion 102A and the bottom surface of the passivation layer 106 may be coplanar due to the planarization process.

Referring to FIG. 5D, bumps 410 contacting the protrusions 102A may be formed. The bumps 410 are formed to contact the entire or part of the bottom surfaces S of the protrusions 102A, and the bumps 410 may be formed to be stretched to the bottom surfaces of the passivation layers 106. The bumps 410 may include a three-layered metal bump. The bumps 410 may include a copper (Cu) layer 410A, a nickel (Ni) layer 410B, and a gold (Au) layer 410C, which are sequentially stacked on the bottom surface S of the protrusion 102A. Although not illustrated, the bumps 410 may include a two-layered metal bump or a single-layered metal bump.

Referring to FIG. 6A, through-substrate vias 102 penetrating through a semiconductor substrate 100 and having protrusions 102A are formed. Since specific methods for forming the through-substrate vias 102 each having a liner layer 101A, a barrier layer 101B, and a through-electrode 101C have been described in the formerly-described embodiment of the present invention, descriptions of them are omitted.

Referring to FIG. 5B, a first insulation layer 210, a second insulation layer 220, and a third insulation layer 230 are sequentially stacked on the backside of the semiconductor substrate 100. A sacrificial layer 240 for a planarization process may be formed over the second metal barrier layer 230. The first insulation layer 210 may be a nitride layer or a silicon oxynitride layer, the second insulation layer 220 may be an oxide layer, the third insulation barrier layer 230 may be a nitride layer or a silicon oxynitride layer, and the sacrificial layer 240 may be an oxide layer.

Referring to FIG. 6C, the backside structure of the semiconductor substrate is planarized. The planarization process may be a CMP process or a mechanical polishing process. The planarization process may be performed to reveal the through-electrodes 101C and the second metal barrier layer 230. As a result of the planarization process, the bottom surfaces S of the protrusions 102A are exposed. The patterned first insulation layer 210A, the patterned second insulation layer 220A, and the patterned third layer 230A obtained as a result of the planarization process are referred to as a passivation layer 200 for convenience in the description

Referring to FIG. 6D, bumps 410 contacting the protrusions 102A may be formed. The bumps 410 are formed to contact the entire or part of the bottom surfaces S of the protrusions 102A, and the bumps 410 may be formed to be stretched to bottom surfaces of the passivation layers 200. The bumps 410 may be a three-layered metal bump. The bumps 410 may include a copper (Cu) layer 410A, a nickel (Ni) layer 410B, and a gold (Au) layer 410C, which are sequentially stacked on the bottom surface S of the protrusion 102A. Although not illustrated, the bumps 410 may include a two-layered metal bump or a single-layered metal bump.

The semiconductor package may have a barrier function by forming an insulation layer on the backside of a semiconductor substrate, e.g., a silicon substrate, from which through-substrate vias (through-silicon vias) are protruded. When the overlay margins between the through-substrate vias on the backside of the semiconductor substrate and the bumps are small, electrical bridges between the semiconductor substrate and the bumps may be prevented.

The semiconductor package having a TSV structure described above may be applied to various kinds of semiconductor devices and package modules having the same.

Referring to FIG. 7, a semiconductor package in accordance with an embodiment of the present invention may be applied to an electronic system 710. The electronic system 710 may include a controller 711, an input/output unit 712, and a memory 713. The controller 711, the input/output unit 712 and the memory 713 may be coupled with one another through a bus 715 providing a path through which data moves.

For example, the controller 711 may include at least any one of at least one microprocessor, at least one digital signal processor, at least one microcontroller, and logic devices capable of performing the same functions as those of these components. The controller 711 and the memory 713 may include at least any one of the semiconductor packages according to the embodiments of the present invention. The input/output unit 712 may include at least one selected among a keypad, a keyboard, a display device, a touch screen and so forth. The memory 713 is a device for storing data. The memory 713 may store data and/or commands to be executed by the controller 711, and the like.

The memory 713 may include a volatile memory device such as a DRAM and/or a nonvolatile memory device such as a flash memory. For example, a flash memory may be mounted to an information processing system such as a mobile terminal or a desk top computer. The flash memory may constitute a solid state disk (SSD). In this case, the electronic system 710 may stably store a large amount of data in a flash memory system. Without being limited thereto, however, the semiconductor device having the semiconductor package of the present invention is applied to SRAM (Static Random Access Memory), flash memory, FeRAM (Ferroelectric Random Access Memory), MRAM (Magnetic Random Access Memory), PRAM (Phase Change Random Access Memory), and the like.

The memory 713 for storing data and the controller 711 for controlling the memory 713 may include one of the semiconductor devices having the semiconductor packages in accordance with the embodiments of the present invention. The memory 713 including the semiconductor device in accordance with this embodiment may include a TSV structure. The TSV structure includes a semiconductor substrate, a through-substrate via including a through-electrode penetrating through the semiconductor substrate and having a protrusion that protrudes from a backside of the semiconductor substrate, and a passivation layer formed on the backside of the semiconductor substrate. A bottom surface of the protrusion and a bottom surface of the passivation layer are substantially coplanar.

The passivation layer includes a first insulation layer formed on the sidewalls of the protrusion and the backside of the semiconductor substrate, and a second insulation layer formed over the first insulation layer.

The through-electrode includes a diffusible metal selected from the group consisting of copper (Cu), tin (Sn), silver (Ag), and combinations thereof. The first insulation layer may be a buffering layer, and the second insulation layer may be a metal barrier layer. Also, the first insulation layer may be a metal barrier layer, and the second insulation layer may be a buffering layer. The metal barrier layer may include a nitride layer or a silicon oxynitride layer, and the buffering layer may include an oxide layer. In another embodiment of the present invention, the first insulation layer formed on the sidewalls of the protrusion and the first insulation layer formed on the backside of the semiconductor substrate are substantially perpendicular. The protrusion of the through-substrate via and the first insulation layer formed on the sidewalls of the protrusion are substantially coaxial. The first insulation layer substantially surrounds the second insulation layer except the bottom surface of the second insulation layer.

The TSV structure further includes a bump contacting the protrusion of the through-substrate via. The bump is formed to be stretched to the bottom surface of the passivation layer.

The through-substrate via includes a liner layer formed on the sidewalls of the protrusion of the through-substrate via, the liner layer is interposed between the first insulation layer and the through-electrode. The through-substrate via further includes a barrier layer interposed between the liner layer and the through-electrode.

When the overlay margins between the through-substrate vias on the backside of the semiconductor substrate and the bumps are small, electrical bridges between the semiconductor substrate and the bumps may be prevented. The semiconductor package having a TSV structure described above may be applied to various kinds of semiconductor devices and package modules having the same.

The electronic system 710 may further include an interface 714 suitable for transmitting data to and receiving data from a communication network. The interface 714 may be a wired type or a wireless type. For example, the interface 714 may include an antenna or a wired transceiver or a wireless transceiver.

The electronic system 710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

When the electronic system 710 is equipment capable of performing a wireless communication, the electronic system 710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

FIG. 8 is a block diagram illustrating an example of an electronic apparatus that may include the semiconductor devices having the semiconductor packages in accordance with the embodiments of the present invention.

Referring to FIG. 8, the semiconductor devices having the semiconductor packages in accordance with the embodiments may be provided in the form of a memory card 800. For example, the memory card 800 may include a memory 810 such as a nonvolatile memory device and a memory controller 820. The memory 810 and the memory controller 820 may store data or read stored data.

The memory 810 may include at least any one among nonvolatile memory devices to which the packaging technology of the embodiments of the present invention is applied. The memory controller 820 may control the memory 810 such that stored data is read out or data is stored in response to a read/write request from a host 830.

While the present invention has been described with respect to the specific embodiments, it will be apparent to those skilled in the art that various changes and modifications may be made without departing from the spirit and scope of the invention as defined in the following claims.

What is claimed is:

1. A through-substrate via structure, comprising:
a semiconductor substrate through which an ion of a metal is diffusible;
a through-substrate via including a through-electrode penetrating through the semiconductor substrate and having a protrusion that protrudes from a backside of the semiconductor substrate; and
a passivation layer formed on a sidewall of the protrusion and the backside of the semiconductor substrate, wherein a bottom surface of the protrusion and a bottom surface of the passivation layer are substantially coplanar,
wherein the passivation layer includes a first insulation layer formed on a sidewalls of the protrusion and the backside of the semiconductor substrate, and a second insulation layer formed over the first insulation layer.

2. The through-substrate via structure of claim 1, wherein the metal is selected from the group consisting of copper (Cu), tin (Sn), silver (Ag), and combinations thereof.

3. The through-substrate via structure of claim 1, wherein the first insulation layer is formed on the sidewall of the protrusion and the backside of the semiconductor substrate.

4. The through-substrate via structure of claim 3, wherein the first insulation layer is a metal barrier layer, and the second insulation layer is a buffering layer.

5. The through-substrate via structure of claim 4, wherein the metal barrier layer includes a nitride layer or a silicon oxynitride layer, and the buffering layer includes an oxide layer.

6. The through-substrate via structure of claim 3, wherein the first insulation layer formed on the sidewall of the protrusion and the first insulation layer formed on the backside of the semiconductor substrate are substantially perpendicular.

7. The through-substrate via structure of claim 3, wherein the protrusion of the through-substrate via and the first insulation layer formed on the sidewall of the protrusion are substantially coaxial.

8. The through-substrate via structure of claim 3, wherein the first insulation layer substantially surround the second insulation layer except a bottom surface of the second insulation layer.

9. The through-substrate via structure of claim 1, further comprising:
a bump contacting the protrusion.

10. The through-substrate via structure of claim 9, wherein the bump is formed to be stretched to the bottom surface of the passivation layer.

11. The through-substrate via structure of claim 3, wherein the through-substrate via comprises a liner layer formed on the sidewall of the protrusion, and the liner layer is interposed between the first insulation layer and the through-electrode.

12. The through-substrate via structure of claim 1, wherein the through-substrate via further comprises a barrier layer interposed between the liner layer and the through-electrode.

13. A semiconductor package, comprising:
through-substrate vias each penetrating through a semiconductor substrate and having a protrusion that protrudes from a backside of the semiconductor substrate; and
a passivation layer formed on a sidewall of the protrusion and the backside of the semiconductor substrate,
wherein a bottom surface of the protrusion and a bottom surface of the passivation layer are substantially coplanar,
wherein the passivation layer includes a first insulation layer formed on a sidewalls of the protrusion and the backside of the semiconductor substrate, a second insulation layer formed over the first insulation layer, and a third insulation layer formed over the second insulation layer.

14. The semiconductor package of claim 13, wherein the first insulation layer formed on the sidewall of the protrusion and the first insulation layer formed on the backside of the semiconductor substrate are substantially perpendicular.

15. The semiconductor package of claim 13, wherein the protrusion and the first insulation layer formed on the sidewall of the protrusion are substantially coaxial.

16. The semiconductor package of claim 13, wherein the first insulation layer is a first metal barrier layer, and the second insulation layer is a buffering layer, and the third insulation layer is a second metal barrier layer.

17. The through-substrate via structure of claim 16, wherein the first metal barrier layer includes a nitride layer or a silicon oxynitride layer, the buffering layer includes an oxide layer, and the second metal barrier layer includes a nitride layer or a silicon oxynitride layer.

18. The semiconductor package of claim 13, wherein the first insulation layer and the third insulation layer surround the second insulation layer except an end of the second insulation layer near the protrusion.

19. The semiconductor package of claim 18, wherein the end of the second insulation layer substantially surrounds the protrusion.

20. The semiconductor package of claim 13, further comprising:
bumps contacting the bottom surface of the protrusion of each of the through-substrate vias.

21. The semiconductor package of claim 13,
wherein the passivation layer includes a first insulation layer formed on the sidewall of the protrusion and the backside of the semiconductor substrate, a second insulation layer formed over the first insulation layer, and a third insulation layer formed over the second insulation layer.
